(19) United States
(12) Patent Application Publication
(10) Pub. No.: US 2009/0121903 A1
(43) Pub. Date: May 14, 2009

(54) USER INTERFACE WITH PHYSICS ENGINE FOR NATURAL GESTURAL CONTROL

(75) Inventor: Thomas J. Misage, San Francisco, CA (US)

Correspondence Address: MICROSOFT CORPORATION, ONE MICROSOFT WAY, REDMOND, WA, 98052, US

(73) Assignee: MICROSOFT CORPORATION, Redmond, WA (US)

(21) Appl. No.: 12/163,526

(22) Filed: Jun. 27, 2008

Related U.S. Application Data
(60) Provisional application No. 60/987,399, filed on Nov. 12, 2007.

(51) Int. Cl. H03K 17/94; G06F 3/048

(52) U.S. Cl. 341/20; 715/863

(57) ABSTRACT

A UI (user interface) for natural gestural control is an electromechanical device that receives user inputs in order to provide an enhanced list and grid navigation experience. In various illustrative examples, the UI includes a touch sensitive surface assembly for receiving a finger or other user input device. A sensor array, which is located beneath the touch sensitive surface assembly, is used to determine a position of the finger on the touch sensitive surface assembly. A single mechanical, momentary contact switch is activated by the sensor array in response to receipt of the finger so that both gestural analog and momentary digital inputs are accepted from the user through the user input device. In some examples, both auditory and tactile feedback it provided to the user when momentary digital inputs are accepted.

### STATEMENT OF RELATED APPLICATION

This application claims the benefit of U.S. Provisional Patent Application Ser. No. 60/987,399, filed Nov. 12, 2007, entitled “User Interface With Physics Engine For Natural Gestural Control”, which is incorporated by reference herein in its entirety.

### BACKGROUND

A central attribute that determines a product's acceptability is usefulness, which measures whether the actual uses of a product can achieve the goals the designers intend them to achieve. The concept of usefulness breaks down further into utility and usability. Although these terms are related, they are not interchangeable. Utility refers to the ability of the product to perform a task or tasks. The more tasks the product is designed to perform, the more utility it has.

Consider typical Microsoft® MS-DOS® word processors from the late 1980s. Such programs provided a wide variety of powerful text editing and manipulation features, but required users to learn and remember dozens of arcane keystrokes to perform them. Applications like these can be said to have high utility (they provide users with the necessary functionality) but low usability (the users must expend a great deal of time and effort to learn and use them). By contrast, a well-designed, simple application like a calculator may be very easy to use but not offer much utility.

Both qualities are necessary for market acceptance, and both are part of the overall concept of usefulness. Obviously, if a device is highly usable but does not do anything of value, nobody will have much reason to use it. And users who are presented with a powerful device that is difficult to use will likely resist it or seek out alternatives.

The development of user interfaces (“UIs”) is one area in particular where product designers and manufacturers are expending significant resources. While many current UIs provide satisfactory results, additional utility and usability are desirable.

This Background is provided to introduce a brief context for the Summary and Detailed Description that follow. This Background is not intended to be an aid in determining the scope of the claimed subject matter nor be viewed as limiting the claimed subject matter to implementations that solve any or all of the disadvantages or problems presented above.

### SUMMARY

A UI (user interface) for natural gestural control is an electromechanical device that receives user inputs in order to provide an enhanced list and grid navigation experience. In various illustrative examples, the UI includes a touch sensitive surface assembly for receiving a finger or other user input device. A sensor array, which is located beneath the touch sensitive surface assembly, is used to determine a position of the finger on the touch sensitive surface assembly. A single mechanical, momentary contact switch is activated by the sensor array in response to receipt of the finger so that both gestural analog and momentary digital inputs are accepted from the user through the user input device. In some examples, both auditory and tactile feedback it provided to the user when momentary digital inputs are accepted.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### DESCRIPTION OF THE DRAWINGS

FIG. 1 shows an illustrative environment including a portable media player in which the present user interface with physics engine for natural gestural control may be implemented;

FIG. 2 shows an exploded assembly view of an illustrative GPad;

FIG. 3 shows details of the touchpad in an isometric view of its back surface;

FIG. 4 shows an exploded assembly view of an illustrative touchpad;

FIG. 5 shows an end-user interacting with the GPad using a scrub or fling gesture;

FIG. 6 shows an illustrative arrangement in which a gesture engine receives gesture events;

FIG. 7 is a flowchart for an illustrative scrub event;

FIG. 8 is UML (unified modeling language) diagram for an illustrative architecture that supports the present user interface with physics engine for natural gestural control;

FIG. 9 shows an illustrative chart which plots pitch/attenuation against UI velocity; and

FIG. 10 shows an illustrative chart which plots attenuation for several velocity brackets.

### DETAILED DESCRIPTION

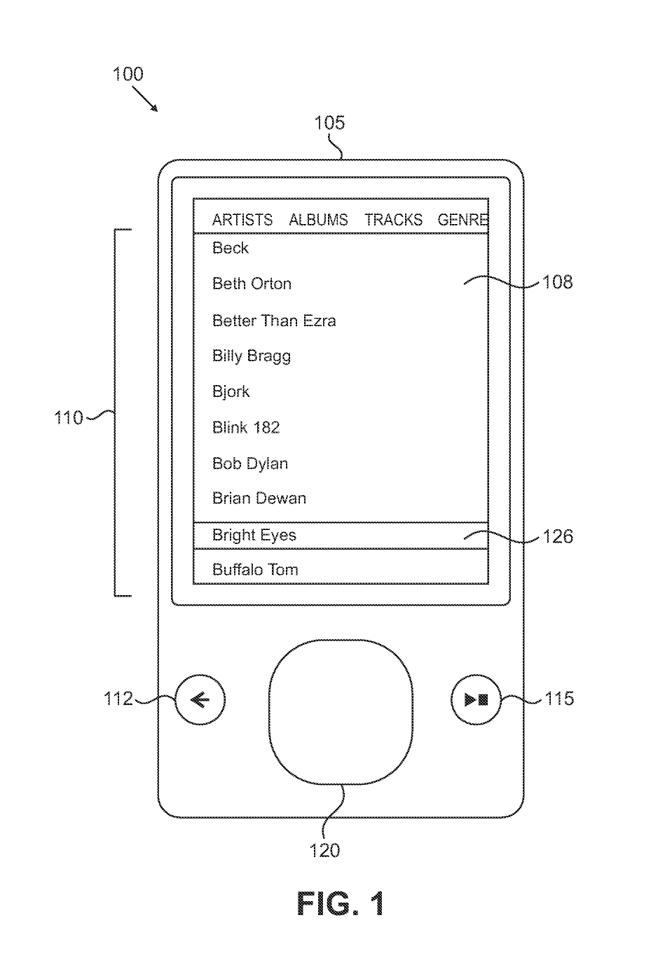

FIG. 1 shows an illustrative environment 100 including a portable media player 105 in which the present user interface (“UI”) with physics engine for natural gestural control may be implemented. The portable media player is configured to render media including music, video, images, text, photographs, etc. in response to end-user input to a UI. To this end the media player includes well-known components such as a processor, a storage medium for storing digital media content, a codec for producing analog signals form the digital media content, and the like.

The user interface utilizes a display device for showing menus and listing stored content, for example, as well as input devices or controls through which the end-user may interact with the UI. In this example, the portable media player 105 includes a display screen 108 and several user controls including buttons 112 and 115, and a gesture pad (called a “GPad”) 120 that operates as a multi-function control and input device. As the buttons 112 and 115 are placed on either side of the Gpad 120, they are referred to here as side buttons.

Buttons 112 and 115 in this illustrative example function conventionally as “back” and “play/pause” controls. The Gpad 120 provides the conventional 5 way D-pad (up/down/left/right/OK (i.e., “enter”) functionality as well as supporting UI gestures as described in more detail below.

The display screen 108 shows, in this example, a UI that includes a list 110 of media content stored on the media player 105 (such as music tracks). It is emphasized that while a list 110 is shown, the term “list” can be generalized to mean a list of line items, a grid, or any series of items. The media player 105 is typically configured to display stored content using a variety of organizational methodologies or schemas (e.g., the content is listed by genre, by artist name, by album name, by track name, by playlist, by most popular etc.). In FIG. 1, a list of artists is shown in alphabetical order with one artist being emphasized via a highlight 126. While an end-user may interact with the UI using gestures as described below, input on the GPad 120 can also mimic the up and down button clicks on a conventional D-pad to scroll up and down the list.

In this illustrative UI, the content lists are placed side by side in a pivoting carousel arrangement. Again, while an end-user may interact with the UI using gestures as described below, input on the on the GPad 120 can also mimic the left and right clicks of a conventional D-pad to pivot among different lists in the carousel. While not shown in the FIG. 1, grids of thumbnails for photographs and other images may be displayed by the media player 105 and accessed in a similar pivoting manner.

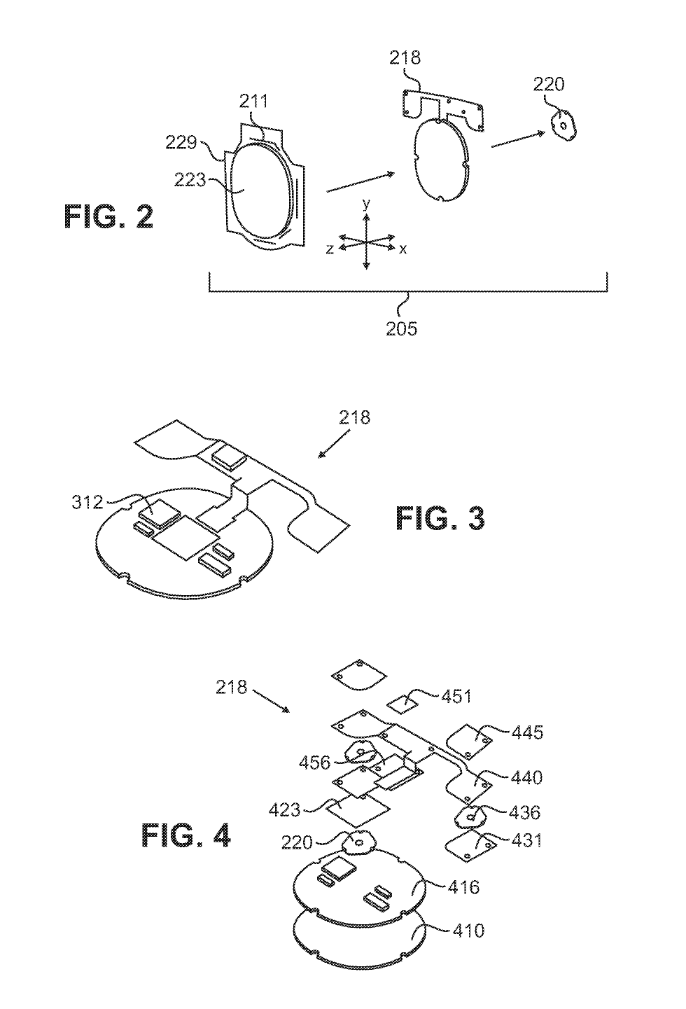

As shown in an exploded assembly view in FIG. 2, GPad 120 comprises a touch sensitive human interface device (“HID”) 205, which includes a touch surface assembly 211 disposed against a sensor array 218, which in this illustrative example, the sensor array 218 is configured as a capacitive touch sensor. The sensor array 218 is disposed against a single mechanical switch, which is configured as a snap dome or tact switch 220 in this example. The components shown in FIG. 2 are further assembled into a housing (not shown) that holds the tact switch 220 in place while simultaneously limiting the motion of the touch surface.

The GPad 10 is arranged so when an end-user slides a finger or other appendage across the touch surface assembly 211, the location of the end user's finger relative to a two dimensional plane (called an “X/Y” plane”) is captured by the underlying sensor array 218. The input surface is oriented in such a manner relative to the housing and single switch 220 that the surface can be depressed anywhere across its face to activate (i.e., fire) the switch 220.

By combining the tact switch 220 with the location of the user's touch on the X/Y plane, the functionality of a plurality of discrete buttons, including but not limited to the five buttons used by the conventional D-pad may be simulated even though only one switch is utilized. However, to the end-user this simulation is transparent and the GPad 120 is perceived as providing conventional D-pad functionality.

The touch surface assembly 211 includes a touchpad 223 formed from a polymer material that may be arranged to take a variety of different shapes. As shown in FIGS. 1 and 2, the touchpad 223 is shaped as a combination of a square and circle (i.e., substantially a square shape with rounded corners) in plan, and concave dish shape in profile. However, other shapes and profiles may also be used depending upon the requirements of a particular implementation. The touchpad 223 is captured in a flexure spring enclosure 229 which functions to maintain the pad 223 against a spring force. This spring force prevents the touchpad 223 from rattling, as well as providing an additional tactile feedback force against the user's finger (in addition to the spring force provided by the tact switch 220) when the touchpad 223 is pushed in the “z” direction by the user when interacting with the GPad 120. This tactile feedback is received when the user pushes not just the center of the touchpad 223 along the axis where the switch 220 is located, but for pushes anywhere across its surface. The tactile feedback may be supplemented by auditory feedback that is generated by operation of the switch 220 by itself, or be generated through playing of an appropriate sound sample (such as a pre-recorded or synthesized clicking sound) through an internal speaker in the media player or via its audio output port.

The back side of sensor array 218 is shown in FIG. 3 and as an exploded assembly in FIG. 4. As shown in FIG. 4, various components (collectively identified by reference numeral 312) are disposed on the back of the sensor array 218. As shown in FIG. 4, a touch pad adhesive layer is placed on the touchpad 416. An insulator 423 covers the tact switch 220. Side buttons are also implemented using a tact switch 436 which are similarly covered by a side button insulator 431. A flex cable 440 is used to couple the switches to a board to board connector 45 1. A stiffener 456 is utilized as well as side button adhesive 445, as shown.

The GPad 120 provides a number of advantages over existing input devices in that it allows the end-user to provide gestural, analog inputs and momentary, digital inputs simultaneously, without lifting the input finger, while providing the user with audible and tactile feedback from momentary inputs. In addition, the GPad 120 uses the sensor array 218 to correlate X and Y position with input from a single switch 220. This eliminates the need for multiple switches, located in various x and y locations, to provide a processor in the media player with a user input registered to a position on an X/Y plane. The reduction of the number of switches comprising an input device reduces device cost, as well as requiring less physical space in the device.

In addition to accepting button clicks, the UI supported by the media player 105 accepts gestures from the user. The gestures, as noted above include in this example, scrub, fling and brake. In this example, UI is an inertial list that mimics the behavior of something that is physically embodied like a wheel on a bicycle that is turned upside down for repair or maintenance.

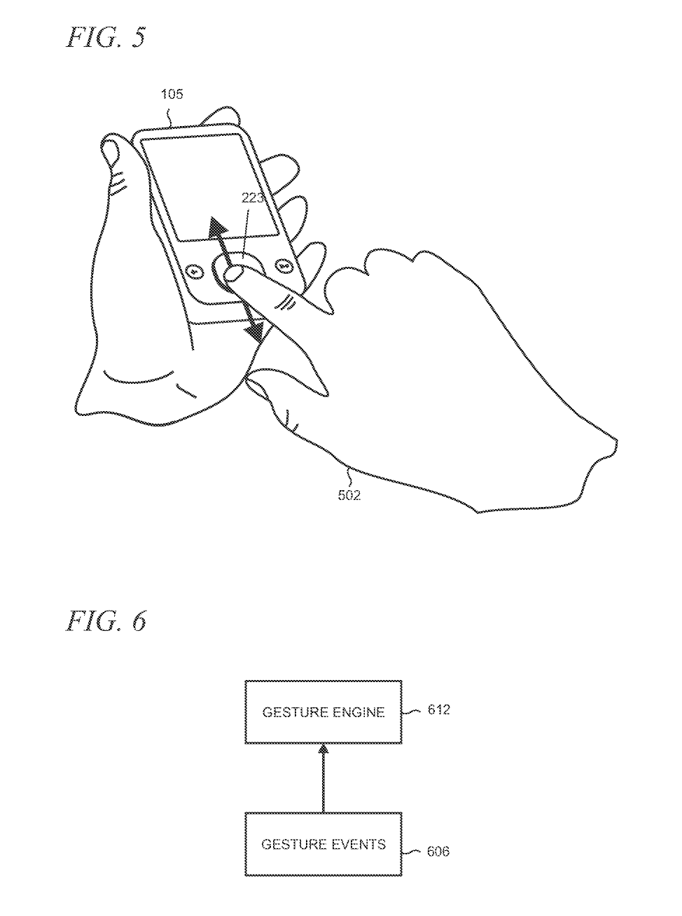

The UI responds to scrubbing gestures by moving the highlight 126 incrementally and proportionally as the end-user moves their finger on the touchpad 223 as indicated by the arrow as shown in FIG. 5. While an up and down motion is shown for purposes of this example, gestures may be made in other directions as well.

The UI responds to the faster flinging gestures, in which the user rapidly brushes their finger across the surface of the GPad 120, by moving fluidly and with a scrolling velocity proportional to the fling in the direction of the fling. The user can make the list 110 move faster by executing a faster fling or by adding subsequent faster flings until they reach the speed of their choice (or the maximum speed). This allows the user to “coast” through a list of items at a speed of their choice. If this speed is particularly fast and the list is going by too fast to read the entries, the UI may be optionally arranged to “pop up” and display the letter of the alphabet that corresponds to the contents of the coasting list 110 on the screen 108 of the media player 105. As the list continues to coast, successive letters pop up as an aide to the end-user in navigation to a desired listing.

Once this speed is set, the list 110 begins to coast and slow down based on “physics” defined through code in a UI physics engine which is used to model the behavior for the inertial UI. After the list 110 starts coasting, any fling is additive regardless of how fast the fling motion is. This makes it easier for the end-user to speed the list motion up. If the end-user allows the list 110 to coast on its own, it will ultimately stop just as if air resistance or friction the bicycle's wheel bearing were acting upon a physically embodied object. The end-user may also choose to keep the list 110 coasting by adding fling gestures from time to time.

The end-user may also choose to slow down or stop the coasting by touching the GPad 120 without moving their finger. A brief touch will slow the coasting down. A longer touch will stop the coasting. The speed of the braking action is also determined by the UI physics code. This braking action only occurs while the user's touch is in a “dead-zone” surrounding their initial touch position. This dead-zone is determined by the gesture engine and ensures that braking does not occur when the user is trying to scrub or fling. The user can also brake instantly by clicking anywhere on the GPad 120, bringing the list motion to an immediate stop.

Because the inertial UI for the GPad 120 relies upon a UI physics engine in which several physics parameters interact to cause a sense of natural motion and natural control, the UI can be set to behave in different ways in response to the end-user's gestures. For example, the friction applied to the motion of the list 110 can be changed, resulting in the list 110 coasting further on each fling. Alternatively, the parking velocity can be regulated to determine how quickly a list that is coasting slowly will snap to a position and stop. Similarly, the braking power can be set to very fast, soft, or some value in between. In most typical implementations, variations of these parameters will be made as a matter of design choice for the UI during its development. However, in other implementations, control of such parameter could be made available for adjustment by the end-user.

In many situations, it is expected that the end-user will start with a scrub and then fluidly move on to a fling (by lifting their finger off the Gpad 120 in the direction of motion to “spin: the list). This is termed a “scrub+fling” gesture. As the end-user releases control of the list 110 and allows it to coast, the UI physics engine provides parameters to ensure that the velocity upon release of the scrub is consistent with the velocity of the scrub. Matching the velocities in this way makes the transition look and feel fluid and natural. This is necessary because, for a given set of gesture engine parameters, the number of items moved by scrubbing across the touchpad 223 can be anywhere from one to several. For the same physical input gesture, this means that the gesture engine may produce different on-screen velocities as the user scrubs. The physics engine allows synchronization of this onscreen velocity with the coasting velocity upon release of the scrub+fling gesture.

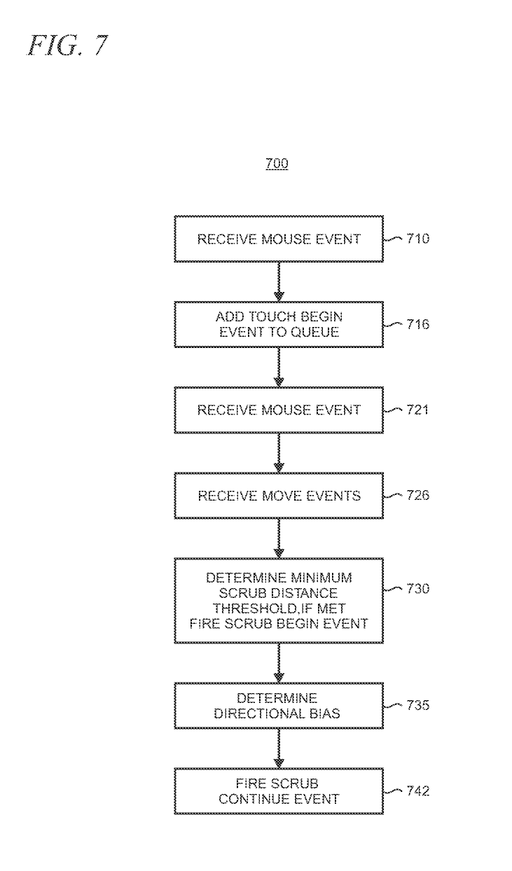

As shown in FIG. 6, the inertial UI in this example does not react to touch data from the GPad 120, but rather to semantic gesture events 606 as determined by a gesture engine 612. An illustrative scrub behavior is shown in the flowchart 700 shown in FIG. 7. Note that user motions are filtered by a jogger mechanism to produce the gesture events.
At block 710, the gesture engine 612 receives a mouse_event when a user touches the GPad 120:
a. dwFlags—MOUSEEVENTF_LEFTDOWN
b. dx
c. dy
d. dwData—should be zero since we're not processing mouse wheel events
e. dwExtraInfo—one bit for identifying input source (1 if HID is attached, 0 otherwise)

This event translates into a TOUCH BEGIN event that is added to a processing queue as indicated by block 716. At block 721, the gesture engine 612 receives another mouse event:
a. dwFlags—MOUSEEVENTF_MOVE
b. dx—absolute position of mouse on X-axis ((0,0) is at upper left corner, (65535, 65535) is the lower right corner)
c. dy—absolute position of mouse on Y-axis (same as X-axis)
d. dwData—0
e. dwExtraInfo—one bit for identifying input source (1 if HID is attached, 0 otherwise)

At block 726, the gesture engine 612 receives eight additional move events which are processed. The initial coordinates are (32000, 4000) which is in the upper middle portion of the touchpad 223, and it is assumed in this example that the user desires to scrub downwards. The subsequent coordinates for the move events are:
1. (32000, 6000)
2. (32000, 8000)
3. (32000, 11000)
4. (32000, 14500)
5. (32000, 18500)
6. (32000, 22000)
7. (32000, 25000)
8. (32000, 26500)

Whether this becomes a scrub depends on whether the minimum scrub distance threshold is crossed as shown at block 730. The distance is calculated using the expression:

\sqrt{(xₙ−xₒ)²+(yₙ−yₒ)²}

Where xₒ and yₒ are the initial touch point, namely (32000, 4000). To avoid a costly square root operation, the minimum scrub distance is a squared and then a comparison is performed.

Assuming the minimum distance threshold for a scrub is 8,000 units, then the boundary will be crossed at coordinate 4, with a y value of 14,500.

If a scrub occurs, the directional bias needs to be known as indicated at block 735. Since the distance calculation provides a magnitude, not a direction, the individual delta x and delta y values are tested. The larger delta indicates the directional bias (either vertical or horizontal). If the delta is positive, then a downward (for vertical movement) or a right (for horizontal movement) movement is indicated. If the delta is negative, then an upward or left movement is indicated.

Throughout the coordinate grid, there is a concept of jogging tick lines. Each time a tick line is crossed, a Scrub Continue event is fired as shown by block 742. In cases, when a tick is directly landed on, no event is triggered. For vertical jogging, these tick lines are horizontal and a tick size parameter controls their distance from each other. The tick line locations are determined when scrubbing begins; the initial tick line intersects the coordinates where the scrub began. In our example, scrubbing begins at y=12000 so a tick line is placed at y=12000 and N unit intervals above and below that tick line. If N is 3,000, then this scrub would produce additional lines at y=3000, y=6000, y=9000, y=15000, y=18000, y=21000, y=24000, y=27000, y=30000, etc . . . Thus, by moving vertically downwards, we'd cross tick lines for the following coordinates:
#5 (past y=15000 and past y=18000)
#6 (past y=21000)
#7 (past y=24000)
   Note that once a tick line is passed, it cannot trigger another Scrub Continue event until another tick line is crossed or the gesture ends. This is to avoid unintended behavior that can occur due to small back and forth motions across the tick line.

Now, with coordinates 9 and 10:
9. (32000, 28000)
10. (36000, 28500)
   In this case, coordinate #9 will trigger another Scrub Continue event. However, for coordinate #10, the user has shifted to the right. No special conditions are needed here—the scrub continues but the jogger does nothing to the input since another tick line has not been crossed. This may seem odd since the user is moving noticeably to the right without continuing downward. However, that does not break the gesture. This is because the jogger keeps scrubs to one dimension.

In summary, a scrub begins when a touch movement passes the minimum distance threshold from the initial touch. The parameters used for gesture detection include the Scrub Distance Threshold which is equivalent to the radius of the “dead zone” noted above. Scrub motion is detected as an end-user's movement passes jogger tick lines. Recall that when a jogger tick line is crossed, it's turned off until another tick line is crossed or the scrub ends. The parameters for gesture detection here are Tick Widths (both horizontal and vertical). The UI physics engine will consider the number of list items moved per scrub event, specifically Scrub Begin and Scrub Continue Events. A scrub is completed when an end-user lifts his or her finger from the touchpad 223.

A fling begins as a scrub but ends with the user rapidly lifting his finger off the Gpad. This will visually appear as the flywheel effect we desire for list navigation. Because the fling starts as a scrub, we still expect to produce a Scrub Begin event. Afterwards, the gesture engine may produce 0 or more Scrub Continue events, depending on the user's finger's motion. The key difference is that instead of just a Scrub End event, we'd first report a Fling event.

The criteria for triggering a Fling event are twofold. First, the user's liftoff velocity (i.e., the user's velocity when he releases his finger from the GPad 120) must exceed a particular threshold, which causes the application to visually entering a “coasting” mode. For example, one could maintain a queue of the five most recent touch coordinates/timestamps. The liftoff velocity would be obtained using the head and tail entries in the queue (presumably, the head entry is the last coordinate before the end-user released his or her finger).

Coasting is defined as continued movement in the UI which is triggered by a fling. The initial coasting velocity (the fling velocity from the UI perspective) is equal to the liftoff velocity multiplied by a pre-determined scale. Note that subsequent coasting velocities are not proportional to a user's initial velocity.

The second requirement is that the fling motion occurs within a predefined arc. To determine this, separate angle range parameters for horizontal and vertical flings will be available. Note that these angles are relative to the initial touch point; they are not based on the center of the GPad 120.

To actually perform the comparison, the slope of the head and tail elements in the recent touch coordinates queue is calculated and compared to the slopes of the angle ranges.

Unfortunately, an issue arises with using angle ranges due to rotated scenes. The initial assumption with angle ranges is that we would use the angle to determine the direction of the fling, so a fling was either horizontal or vertical. Additionally, many application scenes needed to emphasize vertical flings over horizontal flings. Thus, the initial notion was to allow the vertical angle range to be wider than the horizontal range. In cases like video playback, where the media player 105 is rotated, the wider vertical angle range would be a benefit since an end-user's horizontal motion would be translated to a vertical motion by the GPad 120. Thus, the end-user would experience a wider horizontal range, which is appropriate for emphasizing horizontal flings when fast forwarding and rewinding.

To maintain flexibility, not starve either direction, and not require passing application state into the gesture detector, the horizontal and vertical angle ranges may be allowed to overlap. If a fling occurs in the overlapped area, the detector will fire fling events in both directions. The application will then be able to decide which direction to process, depending on which direction it wishes to emphasize.

To illustrate the angle ranges approach, consider this example:
Vertical angle range is 100 degrees
Horizontal angle range is 100 degrees
   where the angle ranges are the same for both directions to maintain symmetry.

To determine if a fling is horizontal, the ending motion must fit within the 100 degree angle. The algorithm to confirm this is:
1. Obtain the minimum and maximum slope by using:

$$\frac{Δ y}{Δ x} = tan \frac{θ}{2} .$$

In this example

$$\frac{θ}{2}$$

is 50 degrees.
2. Obtain the slope of the fling using the oldest coordinate in our recent coordinates queue and the most recent coordinate, which is from the Mouse Up event.
3. Compare the fling slope to the angle slope using:

$$- \frac{Δ y}{Δ x} \leq {slope}_{fling} \leq Δ \frac{y}{Δ x} .$$

If this comparison holds true, the fling meets the requirements to be a horizontal fling.

Once we're coasting, an application will need to apply friction to the movement. Friction is applied in a time-constant multiplicative manner. The equation representing this is

υₜ=υₜ₋₁×(1−drag),

where 0<drag≦.

Thus, the velocity at time t is the velocity at time t-1 multiplied by a friction constant. The drag value is equal to the intrinsic flywheel friction plus the touch friction. The intrinsic flywheel friction and touch friction are both tweak-able parameters.

After the initial fling, the situation becomes more complicated since a fling that occurs during a coast behaves differently from an initial fling. From a UI perspective, the wheel will spin up immediately and continue to coast with the same physics.

To update the velocity for a subsequent fling, a second velocity formula is used. This formula is

υₜ=υₜ₋₁×fling factor

where υₜ₋₁ is the current coasting velocity.

Note that before the subsequent fling, a user will first have to touch the Gpad and initiate a new scrub. To make the transition from one fling to another graceful, braking should only be applied when the touch is in the deadzone of the new scrub. So, as soon as scrubbing begins, the brakes should be released. From a physics perspective, this means that we don't want to decelerate a coast while scrubbing. The end result is that touch the GPad 120 applies brakes to the coast. However, if the end-user flings again, the braking only lasts while in the deadzone. The expectation is that this will improve fling consistency and responsiveness and will make larger, slower flings behave as a user expects.

When a fling occurs during a coast, and the fling is in the opposite direction of the coast, we call it a “reverse fling”. The UI effect is to have the highlighter behave as if hitting a rubber wall; the coast will switch to the opposite direction and may slow down by some controllable factor. The formula for coast speed after a reverse fling is

|υᵣₑᵥₑᵣₛₑ|=υ_{coast|×bounciness}

where 0≦bounciness≦1. Since we know this is a reverse fling, we can change the direction of the coast without incorporating it into the speed formula.

Along with the velocity thresholds for initiating a fling and terminating a coast, there is also a maximum coast velocity. The maximum coast velocity is directly proportional to the size of the list being traversed. This formula for this maximum is

υₘₐₓ=(list size)×(h)

where h is a scaling factor in Hertz.

In the case of multiple flings, the gesture engine input queue would appear as follows:
1. Touch Begin
2. Scrub Begin
3. Scrub Continue
4. Scrub Continue
5. Scrub End
6. Fling
7. Touch End
8. Touch Begin
9. Scrub Begin
10. Scrub End
11. Fling
12. Touch End
13. Touch Begin
14. Scrub Begin
15. Scrub End
16. Fling
17. Touch End

The Scrub Begin and Scrub Continue events trigger movement in an application's list UI. The Fling event provides the fling's initial velocity. Once an application reads the event from the queue, it will need to calculate subsequent velocities as friction is applied. If the application receives another Fling event while the coasting velocity is greater than the fling termination threshold, the coasting velocity should be recalculated as described above.

Thus, the gesture detector is responsible for announcing the Fling event while each application is responsible for applying coasting physics to process the subsequent coasting velocities and behave accordingly.

In summary, a fling begins when an end-user lifts his finger from the GPad 120 with sufficient velocity, and in a direction that fits within specified angle ranges. Note that an end-user must have initiated a scrub before a fling will be recognized. The parameters used for fling detection include coasting instantiation velocity threshold (necessary velocity to detect a Fling, which starts a coast), and angle ranges for horizontal and vertical lines. The UI physics engine will consider the scaling factor (multiplied by liftoff velocity to obtain the end-user's initial coasting velocity in the UI).

As coasting occurs, from the initial fling event, the velocity decreases as the running application applies friction. If an end-user flings again while coasting is occurring, the velocity is updated based on a fling factor. Visually, this appears to accelerate UI movement. The physics parameters considered will include:
Drag coefficient (friction applied to coasting that slows it down) including list drag and touch-induced drag (how much drag a key press adds);
Velocity update delay (how long to wait before updating the velocity to slow down fly wheel effect);
Fling factor (accelerates the fly wheel when a fling is triggered while coasting is occurring);
List scaling factor (multiplied by list size to determine maximum coasting velocity);
Bounciness (decelerates the fly wheel when a reverse fling occurs)

A coast ends when the coasting velocity reaches 0 or some minimum threshold. At this point, an incoming Fling event represents a new fling, as opposed to a desire to accelerate coasting. The physics parameters here include the Coast termination velocity threshold (the threshold where coasting stops).

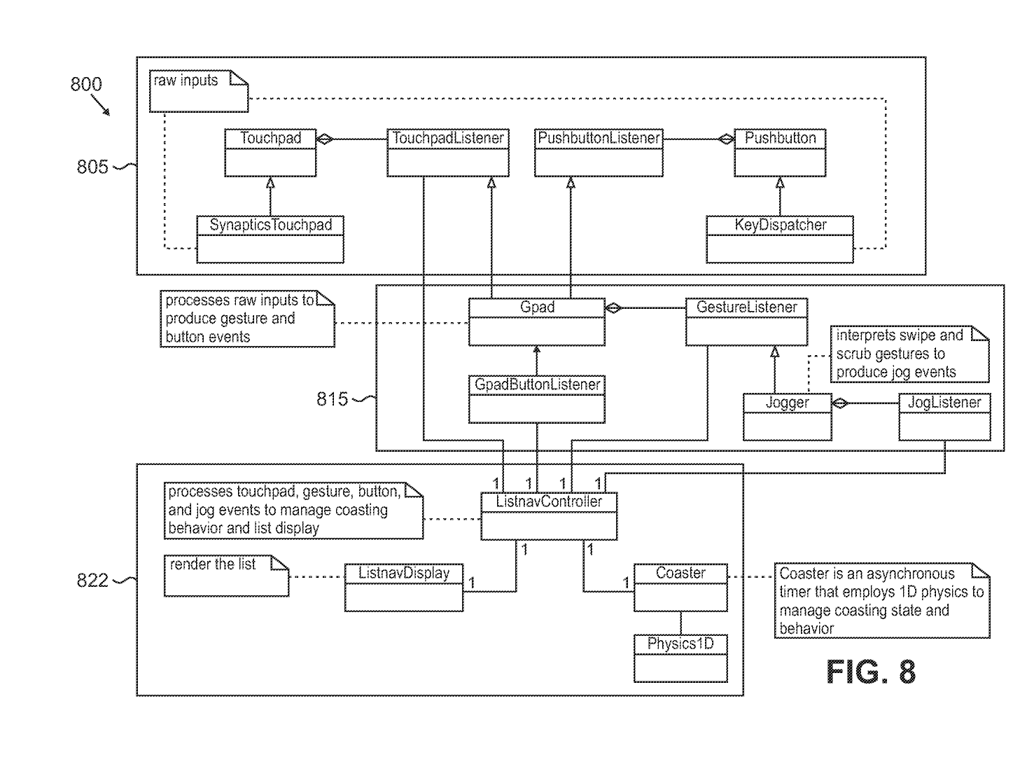

FIG. 8 shows an illustrative architecture expressed in UML for a UI with physics engine for natural gesture control. The architecture 800 includes a GPad driver 805, gesture engine 815, and an application 822. The GPad driver 805 sends keyboard and mouse events to the gesture engine 815 whenever end-user input is detected (i.e., key presses, GPad touches, and GPad movements). The table below shows key parameters from these events:

| Gpad Driver | | | |
|---|---|---|---|
| Output | Pertinent Data | | |
| Keybd_event | dwVKey, fKeyReleased, nInputSource | | |
| Mouse_event | dwBehavior, dwXPosition, dwYPosition, nInputSource | | |
| | | Tick Lines | |
| Parameters | Direction | Crossed | Velocity |
| ScrubBegin | North, South, East, West | N/A | N/A |
| ScrubContinue | North, South, East, West | At least 1 | N/A |
| ScrubEnd | N/A | N/A | N/A |
| Fling | North, South, East, West | N/A | Liftoff Velocity |

Whenever the gesture engine 815 receives a keyboard event; it will need to:
1. Store the Vkey and whether it was presses or released
   a. If the key was already being pressed, check repeat rate
2. Add a Touch Begin event to the input queue
3. Add a KeyPressed or KeyReleased event to the input queue, depending on the action, that indicates which VKey was affected
4. Signal the gesture detector to abandon any gesture processing.
5. Wait for the gesture detector to signal if event(s) should be added to the queue
6. Activate a timeout to prevent further gesture detection.
7. Add a Touch End event to the input queue.

Whenever the gesture engine 815 receives a mouse event, it must:
1. Update the current X, Y coordinates
2. If dwBehavior==MOUSEEVENTF_LEFTDOWN
3. If the timeout to prevent gesture detection is still running, stop it immediately.
4. Add a Touch Begin event to the input queue
5. Signal the gesture detector to begin processing data
6. Wait for the gesture detector to signal if event(s) should be added to the queue
7. Else if dwBehavior==MOUSEEVENTF_LEFTUP
8. Signal the gesture detector that any gesture is finished
9. Wait for the gesture detector to signal if event(s) should be added to the queue
10. Add a Touch End event to the queue
11. Else if dwBehavior==MOUSEEVENTF_MOVE
12. Signal the gesture detector that new touch coordinates are available
13. Wait for the gesture detector to signal if event(s) should be added to the queue

To control gesture detection, a thread is desired that is, by default, waiting on an event that is signaled by the gesture engine 815 when touch data is coming in. Once the gesture engine 815 signals the detector, it may need to wait until the detector finishes processing the input data to see if a gesture event is added to the input queue.

As the gesture engine 815 adds events to the input queue, it will notify the running application; the in-focus application will need to process gesture events to produce specific UI behaviors. In a scene that contains list navigation, an illustrative algorithm for gesture handling could be:

| 1. | If(event == ScrubBegin ∥ event == ScrubContinue) | |
|---|---|---|
| | a. | Signal list navigator that a scrub occurred |

| | |
|---|---|
| i. | Pass scrub direction to list navigator |
| ii. | Inside list navigator |

| | |
|---|---|
| 1. | Translate scrub direction if HID is rotated |
| 2. | List navigator moves highlighter N items in specified direction. Note |
| | that the 1D jogger will filter out scrubs perpendicular to the initial |
| | scrub. |
| 3. | Audible feedback is produced for scrub movements |

| 2. | If(event == ScrubEnd) | |
|---|---|---|
| | a. | Clear any state explicitly used for scrubbing; leave any state |
| | | that’s necessary for flings |
| 3. | If(event == Fling) | |
| | a. | Determine current coasting velocity by multiplying liftoff velocity times |
| | | a specified scaling factor |
| | b. | Signal list navigator that a fling occurred |

| | |
|---|---|
| i. | Pass initial coasting velocity and fling direction to list navigator |
| ii. | Inside list navigator |

| | |
|---|---|
| 1. | Translate fling direction if HID is rotated |
| 2. | Do |

| | |
|---|---|
| a. | If (fCoasting) |

| | |
|---|---|
| i. | If (coasting direction matches fling direction) |

| | |
|---|---|
| 1. | Determine new coasting velocity by |
| | multiplying the current velocity by the fling |
| | factor |

| | |
|---|---|
| ii. | Else |

| | |
|---|---|
| 1. | Determine new coasting velocity using |
| | reverse fling formula |

| | |
|---|---|
| b. | Else |

| | |
|---|---|
| i. | Set fCoasting |

| | |
|---|---|
| c. | If (coasting velocity > maximum coasting velocity) |

| | |
|---|---|
| i. | Set coasting velocity = maximum coasting velocity |

| | |
|---|---|
| d. | Animate list highlighter so it moves N items per time unit in |
| | specified direction |
| e. | Audible feedback is produced for coasting |
| f. | Sleep(velocity update delay) |
| g. | Calculate new coasting velocity after applying flywheel |
| | friction and any touch friction |

| | |
|---|---|
| 3. | While (coasting velocity > coasting threshold) |
| 4. | Terminate list highlighter movement |

| 4. | If(event == KeyPress) | |
|---|---|---|
| | a. | Signal list navigator that a key press occurred |

| | |
|---|---|
| i. | Inside list navigator |

| | |
|---|---|
| 1. | If (coasting velocity > coasting threshold) |

| | |
|---|---|
| a. | Set velocity to 0 or add touch friction to drag |

For an application that has a grid view, there's a desire to use a 2D jogger which would allow scrubs in both horizontal and vertical directions.

One significant difference between the 1D and 2D jogger that deserve attention is how scrub events are initiated. When starting a scrub with the 2D jogger, it's possible that scrubs may be fired for horizontal and vertical directions in the same gesture since we're not only looking for vertical movements anymore. Specifically, imagine a diagonal scrub that simultaneously passes the minimum distance from the touch begin coordinates in both horizontal and vertical directions. In this case, scrubs for both directions must be fired.

From an application's perspective, it will need to filter out gestures it doesn't want depending on its current view. This was the ID jogger's responsibility but since we desire to keep application specifics out of the gesture engine 815, we're choosing to use a 2D jogger that fires events in all cardinal directions and lets the application sort out which gestures to act on.

Below is an illustrative procedure for processing touch input using the 2D jogger:

| 1. | If dwBehavior == MOUSEEVENTF_LEFTDOWN | |
|---|---|---|
| | a. | Store initial touch coordinates along with current timestamp |
| 2. | Else if dwBehavior == MOUSEEVENTF_MOVE | |
| | a. | |
| | b. | If (!fScrubbingBegan &&(dist(current coordinates, initial coordinates) > |
| | | minScrubDistance)) |

| | |
|---|---|
| i. | Enqueue current touch coordinates along with current timestamp |
| ii. | |
| iii. | Trigger 2D jogger |

| | |
|---|---|
| 1. | If (!fJoggingBegan) |

| | |
|---|---|
| a. | Store state to indicate jogging began |
| b. | |
| c. | Determine and store locations of tick lines |
| d. | Determine scrub directions |
| e. | If (currentScrubDirection == HORIZONTAL) |

| | |
|---|---|
| i. | Signal gesture engine to add a Scrub Begin event to |
| | the input queue |

| | |
|---|---|
| f. | Else If (currentScrubDirection == VERTICAL) |

| | |
|---|---|
| i. | Signal gesture engine to add a Scrub Begin event to |
| | the input queue |

| | |
|---|---|
| g. | Else if (currentScrubDirection == (HORIZONTAL && |
| | VERTICAL)) |

| | |
|---|---|
| i. | Signal gesture engine to add a ScrubBegin event to |
| | the input queue for the vertical direction |
| ii. | Signal gesture engine to add a ScrubContinue event |
| | to the input queue for the horizontal direction |

| | |
|---|---|
| 2. | Set fScrubbingBegan |

| | |
|---|---|
| c. | Else if(fScrubbingBegan) |

| | |
|---|---|
| i. | Enqueue current touch coordinates along with current timestamp |
| ii. | Trigger 2D jogger |

| | |
|---|---|
| 1. | If (fJoggingBegan) |

| | |
|---|---|
| a. | Diff current coordinates with previous coordinates |
| b. | Update passed tick lines in both directions |
| c. | If (horizontal tick line passed &&passed tick line != previous |
| | horizontal passed tick line) |

| | |
|---|---|
| i. | Signal gesture engine to add a Scrub Continue event |
| | to the input queue |

| | |
|---|---|
| d. | If (vertical tick line passed &&passed tick line != previous |
| | vertical passed tick line) |

| | |
|---|---|
| i. | Signal gesture engine to add a Scrub Continue event |
| | to the input queue |

| 3. | Else if dwBehavior == MOUSEEVENTF_LEFTUP | |
|---|---|---|
| | a. | If(fScrubbingBegan) |

| | |
|---|---|
| i. | Enqueue current touch coordinates along with current timestamp |
| ii. | Trigger 2D jogger |

| | |
|---|---|
| 1. | If (fJoggingBegan) |

| | |
|---|---|
| a. | |
| b. | Determine slope of coordinates using head and tail |
| | coordinates from queue |
| c. | Determine lift off velocity using distance apart and time |
| | difference between the head and tail coordinates from the |
| | queue |
| d. | If (lift off velocity * scale >= coasting threshold) // First test for |
| | flings |

| | |
|---|---|
| i. | Signal gesture engine to add a Scrub End event to the |
| | input queue |
| ii. | If (slope lies in vertical slope boundaries) |

| | |
|---|---|
| 1. | Signal gesture engine to add a Fling event |
| | (direction is vertical) to the input queue |

| | |
|---|---|
| iii. | If (slope lies in horizontal slope boundaries) |

| | |
|---|---|
| 1. | Signal gesture engine to add a Fling event |
| | (direction is horizontal) to the input queue |

| | |
|---|---|
| e. | Else |

| | |
|---|---|
| i. | Diff current coordinates with previous coordinates |
| ii. | Update passed tick lines in both directions |
| iii. | If (horizontal tick line passed &&passed tick line != |
| | previous horizontal passed tick line) |

| | |
|---|---|
| 1. | Signal gesture engine to add a Scrub |
| | Continue event to the input queue |

| | |
|---|---|
| iv. | If (vertical tick line passed &&passed tick line != |
| | previous vertical passed tick line) |

| | |
|---|---|
| 1. | Signal gesture engine to add a Scrub |
| | Continue event to the input queue |

| | |
|---|---|
| v. | Signal gesture engine to add a Scrub End event to the |
| | input queue |

| | |
|---|---|
| b. | Clear the 1D jogger |
| c. | Clear fScrubbingBegan, tick region values, and recent coordinates queue |
| d. | Signal gesture engine that clean-up is complete |

With a ID jogger, When touch data is received, the detector is signaled by the gesture engine 815 and follows this algorithm:

| 1. | If dwBehavior == MOUSEEVENTF_LEFTDOWN | |
|---|---|---|
| | a. | Store initial touch coordinates along with current timestamp |
| 2. | Else if dwBehavior == MOUSEEVENTF_MOVE | |
| | a. | Enqueue current touch coordinates along with current timestamp |
| | b. | If (!fScrubbingBegan &&(dist(current coordinates, initial coordinates) > |
| | | minScrubDistance)) |

| | |
|---|---|
| i. | Determine scrub direction |
| ii. | Trigger 1D jogger |

| | |
|---|---|
| 1. | If(currentScrubDirection == VERTICAL) |
| a. | If (!fJoggingBegan) |

| | |
|---|---|
| i. | Determine the tick region of current coordinates |
| ii. | Store the tick region (the area between established |
| | tick lines) where jogging began |
| iii. | Store state to indicate jogging began |
| iv. | Signal gesture engine to add a Scrub Begin event to |
| | the input queue |

| | |
|---|---|
| 2. | Set fScrubbingBegan |

| | |
|---|---|
| c. | Else if(fScrubbingBegan) |

| | |
|---|---|
| i. | Determine scrub direction |
| ii. | Trigger 1D jogger |

| | |
|---|---|
| 1. | If (currentScrubDirection == VERTICAL) |

| | |
|---|---|
| a. | If (fJoggingBegan) |

| | |
|---|---|
| i. | Determine the tick region of current coordinates |
| ii. | If (current tick region != previous tick region) |

| | |
|---|---|
| 1. | Store timestamp of current coordinates as |
| | the latest scrub time |
| 2. | Signal gesture engine to add a Scrub |
| | Continue event to the input queue |

| | |
|---|---|
| b. | Else |

| | |
|---|---|
| i. | Determine the tick region of current coordinates |
| ii. | Store the tick region (the area between established |
| | tick lines) where jogging began |
| iii. | Store state to indicate jogging began |
| iv. | Signal gesture engine to add a Scrub Begin event to |
| | the input queue |

| 3. | Else if dwBehavior == MOUSEEVENTF_LEFTUP | |
|---|---|---|
| | a. | Enqueue current touch coordinates along with current timestamp |
| | b. | If(fScrubbingBegan) |

| | |
|---|---|
| i. | Determine scrub direction |
| ii. | Trigger 1D jogger |

| | |
|---|---|
| 1. | If (fJoggingBegan) |

| | |
|---|---|
| a. | If (currentScrubDirection == VERTICAL) |

| | |
|---|---|
| i. | Determine lift off velocity |
| ii. | If (lift off velocity * scale >= coasting threshold) |

| | |
|---|---|
| 1. | Signal gesture engine to add a Scrub End |
| | event to the input queue |
| 2. | Signal gesture engine to add a Fling event to |
| | the input queue |

| | |
|---|---|
| iii. | Else |

| | |
|---|---|
| 1. | Determine the tick region of current |
| | coordinates |
| 2. | If(current tick region != previous tick region) |

| | |
|---|---|
| a. | Signal gesture engine to add a |
| | Scrub Continue event to the input |
| | queue |
| b. | Signal gesture engine to add a |
| | Scrub End event to the input queue |

| | |
|---|---|
| b. | Else |

| | |
|---|---|
| i. | Signal gesture engine to add a Scrub End event to the |
| | input queue |

| | |
|---|---|
| c. | Clear the 1D jogger |
| d. | Clear fScrubbingBegan, tick region values, and recent coordinates queue |
| e. | Signal gesture engine that clean-up is complete |

When a key press occurs, the detector is signaled by the gesture engine to end gesture processing. The algorithm for abrupt termination is:

| 1. | If(fScrubbingBegan) | |
|---|---|---|
| | a. | Signal gesture engine to add a Scrub End Event to the input |
| | | queue |

| | |
|---|---|
| 2. | Clear the 1D jogger |
| 3. | Clear fScrubbingBegan, tick region values, and recent coordinates |
| | queue |
| 4. | Signal gesture engine that clean-up is complete |

A method for using a velocity threshold to switch between gesture-velocity-proportional acceleration,and coasting-velocity-proportional acceleration, to be used when processing Fling gestures while Coasting is now described. While a single multiplicative constant may used on the coasting velocity when accelerating while coasting, this can lead to a chunky, stuttering low-speed coasting experience. Instead, the acceleration of the coasting physics at low speed should be proportional to the speed of the input Fling. At high speed, the old behavior is maintained.

The variables include:
coastingVelocity
   your current coasting velocity
   typical values: −5000 to +5000 Hz
flingVelocity
   the velocity of the gesture
   typical values: −50 to 50 GPadRadii/Second
flingFactorThreshold
   the velocity at which we switch behaviors
   typical value: 0 to 200 Hz—20 is a good start
scale
   a scalar factor to allow overall scaling of the speed of Coasting physics
   typical value: 1.0 to 5.0 unit less—2.0 is a good start

The flingFactor setting may be split for the two ranges to allow for independent adjustment of low and high-speed acceleration profile. The current settings call for the same value of 1.7, but this is a wise place to keep the settings separate, as different functionality is introduced in the two speed ranges:
flingFactorForHighSpeed
   a scalar defining the acceleration of the Coasting physics on subsequent flings once already coasting and above
flingFactorThreshold
   typical value: 1.0 to 5.0 unit less—1.7 is a good start
flingFactorForLowSpeed
   a scalar defining the acceleration of the Coasting physics on subsequent flings once already coasting and below
flingFactorThreshold
   typical value: 1.0 to 5.0 unit less—1.7 is a good start
      Note: The First Fling from a dead stop is always fired with the following velocity ( ): coastingVelocity+=flingVelocity*Scale

The pseudocode follows:

//On a new Fling while coasting:
if (directionOfFling == coastingDirection) {
// we're not turning around
if (coastingVelocity <= flingFactorThreshold) {
// we're going slowly, so add the gesture velocity
coastingVelocity += flingVelocity * flingFactorForLowSpeed * Scale;
} else {
// we're going quickly, so accelerate by multiplying by flingFactor
coastingVelocity += coastingVelocity * flingFactorForHighSpeed * Scale;
}
} else {
// we're turning around
if (coastingVelocity <= flingFactorThreshold) {
// note that we forget the current velocity, and just
// head in the direction of the new fling.
coastingVelocity = flingVelocity * Scale;
} else {
// we're going quickly, so use the old strategy - just bounce back
coastingVelocity = −coastingVelocity
}
}

A method for determining the appropriate maximum coasting speeds for the wheel based on the size of the content being navigated is now described.

In two elements:

1) A simple scalar equation describing the maximum speed in terms of the list size
2) An enforced minimum Max speed to keep short lists from being limited to an unreasonably low speed.

The variables include:
coastingVelocity
   your current coasting velocity
   typical values: −5000 to +5000 Hz
desiredCoastingVelocity
   the new desired coasting velocity based on the pure physics of the wheel—i.e. how fast the wheel is trying to go, if you only listen to the Flings, and don't have a maximum speed. This is used simply to make the P-code more understandable.
desiredCoastingVelocity.getSign( )
   the sign of the velocity—used to convert a Speed into a Velocity maxSpeed
the maximum speed of coasting in a given situation—recalculated
   for each list. Overrides the newCoastingVelocity as necessary to prevent the list going by too fast or being capped too slow.
   Always >0.
   typical values: minMaxSpeed to unlimited (as determined by algorithm)
minMaxSpeed
   the lowest value that maxSpeed is EVER allowed to take—no list may have a lower max speed than this. 75 Hz, magic number.
maxSpeedFactor
   a parameter used in determining maxSpeed based on the size of the list.
   typical values: 0.1 to 5.0—currently using 0.65
listSize
   the number of items in the list being navigated
   Note the accomodations in the P-code for the sign of the velocity.

Care should be taken when setting the positive and negative directions of the GPad, the Physics and the UI. They should always agree, i.e., if down is positive then:
Flinging downwards means positive fling Velocity
Coasting downwards means positive coasting Velocity
Moving down the list means increasing the list index.

When loading a new list, the maximum speed is calculated using the algorithm:

maxSpeed = listSize * maxSpeedFactor;
if (maxSpeed < minMaxSpeed)
maxSpeed = minMax Speed:

When setting the coasting speed, apply the maximum speed as necessary:

coastingVelocity - desiredCoastingVelocity.getsign( ) * //cont’d
min(maxSpeed, abs(desiredCoastingVelocity));

Turning now to the an additional feature provided by the present UI, the user experience provided by the gestures supported by the GPad 120 can be further enhanced through audible feedback in a fashion that would to more closely represent the organic or physical dynamics of the UI and provide more information to the user about the state they were in. For example, a click sound fades out as the UI slows down, or the pitch of the click sound increases as the user moves swiftly through a through a long list.

This form of audible feedback is implemented by programmatically changing the volume/pitch of the audible feedback based upon the velocity the UI. One such methodology includes a fixed maximum tick rate with amplitude enveloping. This uses a velocity threshold to switch between direct and abstract feedback in kinetic interface.

The methodology implements the following:
When scrubbing, a tick asset is played at every step.
When coasting slowly (<20 Hz), a tick asset is played at every element.
When coasting quickly (>20 Hz), a tick asset is played at 20 Hz, and the amplitude is modulated to give an impression of deceleration.
As the speed of the UI decreases below 20 Hz, the asset resumes play at every step.

The amplitude modulation works as follows:
While Scrubbing: Asset is played at fixed volume V1 each time the cursor moves one element.
Coasting Below 20 Hz: Asset is played at fixed volume V1 each time the cursor moves one element.
Coasting Above 20 Hz: On a Fling which results in a speed greater than 20 Hz, volume is set to V2 where (V2>V1).

As the wheel slows due to “friction”, the volume decreases asymptotically to V3, just like the speed of the wheel. Once the velocity falls below 20 Hz, the ticks resume playing at VI on each cursor move. If the user flings again, the volume is again set to V2, and the process is the same. It is noted that volume is note proportional to absolute velocity as it decays with time since the last fling.

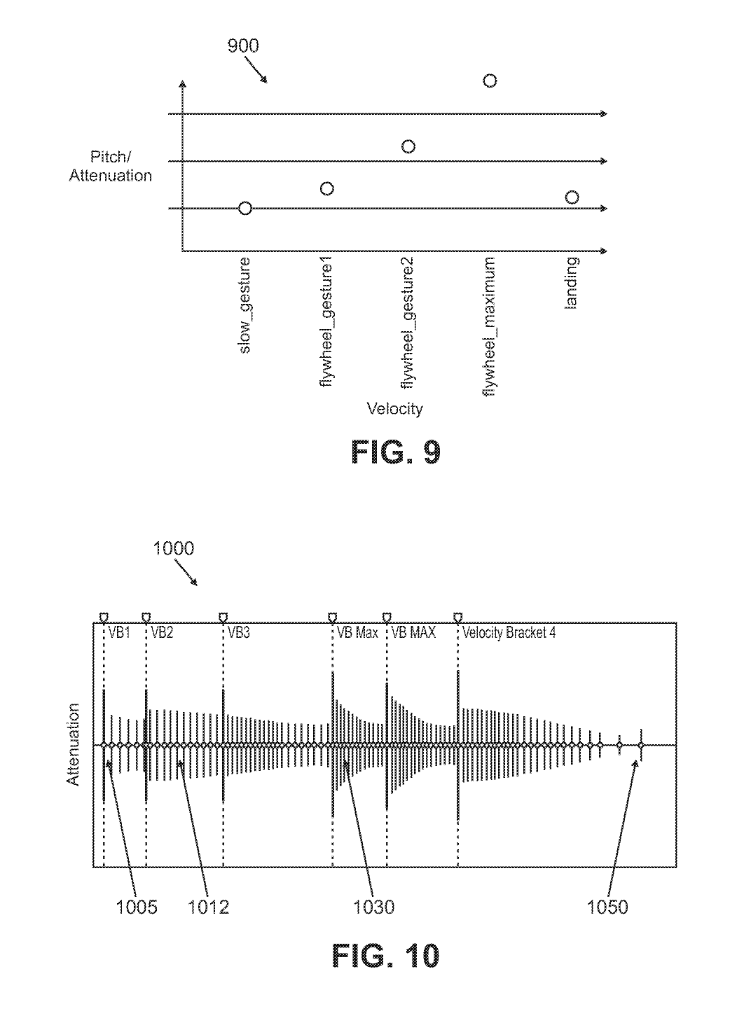

The methodology is shown graphically in FIG. 9 which shows a chart 900 that plots pitch/attenuation as a function of velocity. The audible feedback provided in this example uses pitch to sonically reinforce the UI's velocity. A slow gesture such as that used to move through items on the list 110 one by one uses a lower pitch. As the UI speed Docket No. 321407.01 up, the pitch increases to indicate the speed of the UI is increasing up until a maximum (as indicated by the flywheel_maximum entry on the velocity axis.

Pitch may further be dynamically implemented where a different sound is rendered according to absolute velocity:
From V=0 to V1, render low pitch (pitch X)
From V=V1 to V2, render medium pitch sound (pitch X+)
From V=V2 to V3, render high pitch sound (pitch X++)

FIG. 10 shows an illustrative chart 1000 that shows attenuation for several different velocity brackets (“VB”). The velocity brackets show a circle representing a list item being shown by the UI. As the circles get closer together, more items are scrolling by in a given time interval. As the circles get farther apart, fewer items are s by. When the user performs a gesture to the UI (called a “fly wheeling” gesture here) as indicated by reference numeral 1005, an independent sound triggers on the gesture which reinforces the flywheel like action of the UI. Subsequent standard clicks on the GPad 120, as indicated by reference numeral 1012, will sound at a frequency and volume that are relative to the velocity of the UI movement.

If the UI reaches a velocity larger than “max” (e.g., around 20-30 list items per second, as indicated by reference numeral 1030, then the frequency of the standard clicks are capped at the “max”. Finally, when the UI stops, a separate and distinct “stopping” sound is played, as shown by reference numeral 1050.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. An electromechanical user interface, comprising:
a touch sensitive surface assembly for receiving a user input device;
a sensor array in contact with the touch sensitive surface assembly for determining a position of the user input device on the touch sensitive surface assembly; and
a single mechanical, momentary contact switch activated by the sensor array in response to receipt of the user input device on the touch sensitive surface so that both gestural analog and momentary digital inputs are accepted from the user through the user input device.

2. The user interface of claim 1 in which the sensor array is a capacitive touch sensor.

3. The user interface of claim 1 in which the mechanical switch is a tact switch.

4. The user interface of claim 1 in which the mechanical switch is a snap dome switch.

5. The user interface of claim 1 in which the touch sensitive surface assembly includes a touchpad and a flexure spring arrangement for maintaining the touchpad against a spring force to thereby provide a tactile feedback force against the user input device when received by any surface portion of the touch sensitive surface assembly.

6. The user interface of claim 5 in which the flexure spring arrangement is an enclosure in which the touchpad is captured.

7. A media player, comprising:
a storage medium for storing digital media content;
a codec for producing analog signals from the digital media content;
a processor for supplying the media content to the codec from the storage medium; and
a user interface for accepting and recognizing both gestural analog and momentary digital inputs by determining a position of a user input device in contact with the user interface, said user interface including a sensor array for determining the position of the user input device in contact with the user interface.

8. The media player of claim 7 in which the user interface further comprises a single mechanical switch activated by the sensor array in response to receipt of the user input device.

9. The media player of claim 7 in which the user interface further comprises a touch sensitive surface that receives the user input device.

10. The media player of claim 7 in which the sensor array is a capacitive touch sensor.

11. The media player of claim 8 in which the mechanical switch is a tact switch.

12. The media player of claim 8 in which the touch sensitive surface assembly includes a touchpad and a flexure spring arrangement for maintaining the touchpad against a spring force to thereby provide a tactile feedback force against the user input device when received by any surface portion of the touch sensitive surface assembly.

13. The media player of claim 12 in which the flexure spring arrangement is an enclosure in which the touchpad is captured.

14. The media player of claim 7 in which the user interface is configured to emulate functionality of a plurality of discrete buttons.

15. A method for receiving user input, comprising:
accepting a user input device on a surface;
determining a position of the user input device on the surface; and
correlating the position of the user input device on the surface with activation of a single mechanical switch to thereby emulate functionality of a plurality of discrete buttons.

16. The method of claim 15 in which the user input device is a human appendage.

17. The method of claim 15 further comprising providing tactile feedback upon accepting the user input device on the surface.

18. The method of claim 15 in which user input accepted on the surface includes gestural analog and momentary digital inputs.

19. The method of claim 15 further comprising activating the mechanical switch by receipt of pressure from the user input device on the surface.

20. The method of claim 15 in which the plurality of discrete buttons that are emulated includes up, down, left, right and enter buttons.
